(19) United States
(12) Patent Application Publication
(10) Pub. No.: US 2007/0015349 A1
(43) Pub. Date: Jan. 18, 2007

(54) Method of producing a composite multilayer

(76) Inventors: Patrice Aublanc, Louhans (FR); Frederic Schoenstein, Saint Dartin (FR); Francois Duverger, Monts (FR)

Correspondence Address: Robert E Krebbs;Thelen Reid & Priest, P O Box 640640, San Jose, CA, 95164-0640, US

(21) Appl. No.: 10/557,130

(22) PCT Filed: Oct. 6, 2004
(86) PCT No.: PCT/FR04/50489

§ 371 Date: Nov. 16, 2005

(30) Foreign Application Priority Data
Oct. 7, 2003 (FR) 0311718

(51) Int. Cl. H01L 21/28

(52) U.S. Cl. 438/573

(57) ABSTRACT

The invention concerns a method for fabricating a composite multilayer comprising a stack of layers of electrically conductive material alternating with layers of electrically insulating material, said method comprising the following steps: a) depositing a conductive material, in layer form, on a peel-off surface of a deposit substrate, b) bonding, by applying glue in insulating material, a layer of conductive material deposited on a peel-off surface of a deposit substrate onto a receiving substrate, c) separating, by peeling off, the deposit substrate from the layer of conductive material adhering to the receiving substrate, this separation providing an elementary stack comprising a layer of glue and a layer of conductive material, d) bonding, by applying the glue in insulating material, another layer of the conductive material deposited on a peel-off surface of a deposit substrate, onto the previously obtained elementary stack, e) separating, by peeling off, the deposit substrate from the layer of conductive material adhering to the elementary stack previously obtained, this separation providing a subsequent elementary stack comprising a layer of glue and a layer of conductive material. The method comprises the repetition of steps d) and e) as many times as necessary to obtain a stack having the desired number of elementary stacks.

### TECHNICAL AREA

The technical area of the invention relates to methods for fabricating multilayer composite materials, on micro-metric scale, consisting of stacks of conductive and insulating layers.

### PRIOR ART

Multilayer composites are known for having attractive hyperfrequency properties. In particular, it has been shown that stacks of finely stratified magnetic/insulating multilayers could be used to fabricate good performance hyperfrequency components, such as tuneable filters for example (see document [1]). These composites can also be used to fabricate inductive cores having applications in the domain of radio-frequencies (see documents [2] and [3]).

For these two types of applications, the optimum thickness of the ferromagnetic layers generally lies in the range of 0.1 to 3 μm. Between these layers, it is advantageous to have a narrow thickness of insulator, typically between one third and 3 times the thickness of the ferromagnetic layer to draw maximum benefit from the magnetic properties of the ferromagnetic material, while maintaining sufficient insulating properties to guarantee good hyper-frequency operation.

However, among the composites intended for the above-cited applications, it is difficult to obtain the desired insulator thickness values.

The ferromagnetic layers are generally obtained by vacuum deposit. It is therefore possible to achieve ferromagnetic/insulator alternation. However, as and when the total thickness of the multilayer is increased, the internal stresses within the layers add up and may lead to rupture of the layers and detachments, detrimental to applications.

This is the reason why we have preferred to have recourse to vacuum depositing for only one magnetic layer, on a thin, flexible, organic deposit substrate. This polymer substrate is then used as insulator in subsequent multilayer structuring phases comprising winding or stacking steps and bonding. The thickness of the flexible film is then dictated by considerations of robustness, ability to be handled in vacuum unwinders, ability to withstand temperature rise during depositing with no degradation or mechanical rupture.

Even when proceeding in this manner, unavoidable internal stresses are present in the layers, and these stresses lead to deformations of the deposit substrate and to natural curvatures which may hinder subsequent handling, all the more so since the deposit substrate in polymer is a thin substrate. All these considerations make impossible or highly penalise the use of deposit substrates having a thickness of less than 6 μm.

The purpose of the invention is to enable the fabrication of composite multilayers consisting of a stack of finely divided layers of ferromagnetic material and insulating material, the thickness of the insulating layers being within a desired range and the layers of the multilayer being free of any stresses applied by the substrate.

### DESCRIPTION OF THE INVENTION

This purpose is achieved using a method for fabricating a composite multilayer comprising a stack of layers of electrically conductive material alternating with layers of electrically insulating material, said method being characterized in that it comprises the following steps:

a) depositing an electrically conductive material, in layer form, on a peel-off surface of a deposit substrate,

b) bonding, by application of the glue in electrically insulating material, a layer of said electrically conductive material deposited on a peel-off surface of a deposit substrate, onto a receiving substrate,

c) separating, by peeling off, the deposit substrate from the layer of electrically conductive material adhering to the receiving substrate, this separation providing an elementary stack comprising a layer of glue and a layer of electrically conductive material,

d) bonding, by application of the glue in electrically insulating material, another layer of said electrically conductive material deposited on a peel-off surface of a deposit substrate, onto the elementary stack previously obtained,

e) separating, by peeling off, the deposit substrate from the layer of electrically conductive material adhering to the previously obtained elementary stack, this separation providing a subsequent elementary stack comprising a layer of glue and a layer of electrically conductive material,

the method comprising the repetition of steps d) and e) as many times as necessary to obtain a stack having the desired number of elementary stacks.

Advantageously, the deposit substrate consists of a polymer film and of one or more transfer layers, i.e. one or more layers allowing transfer.

The receiving substrate may be a film or an object on which the elementary stack is plated.

According to a particular embodiment, the receiving substrate is driven in a rotational movement. Advantageously, the separation steps are conducted during winding, after partial winding of the elementary stack around the substrate. Advantageously, the receiving substrate is a cylindrical substrate, a roll for example.

According to a particular embodiment, the steps of depositing, bonding and separation are continuously conducted steps.

Advantageously, the depositing of the electrically conductive material is made by magnetron-assisted sputtering.

Advantageously, the electrically conductive material is a ferromagnetic material. Preferably, it is a soft amorphous or nano-crystallized ferromagnetic material. The ferromagnetic material may for example contain CoFeSiB, CoNbZr or FeNi.

Advantageously, the electrically conductive material is chosen from among a cobalt, iron or nickel-based amorphous ferromagnetic alloy.

Advantageously, the layers of electrically conductive material may be in materials having the same chemical compositions and/or the same electromagnetic properties.

Advantageously, the layers of electrically conductive material may be in materials having different chemical compositions and/or electromagnetic properties.

Advantageously, the layer of electrically conductive material has a thickness of between 0.1 and 10 times the skin depth of the material. It is recalled that skin depth corresponds to the area in which an electromagnetic wave is able to propagate on entering a conductor. More precisely, skin depth is defined as being the depth at which the amplitude of an incident electromagnetic wave is divided by e¹. It is considered that below this depth the wave is attenuated, and above this depth it is propagated.

Advantageously, the layer of glue is deposited on the peel-off surface of a deposit substrate, on the receiving substrate or on both.

Advantageously, the glue can preferably be activated by pressure or temperature. It is to be noted that step d) concerning separation of the deposit substrate from the layer of electrically conductive material can be made continuously, after the contacting step, if the glue used is a fast setting glue. If the glue used is a slow-setting glue, a cross-linking step of said glue must be allowed before proceeding with the detaching of the supporting film.

The glue or glues used are preferably of high tack type, hot or cold-activated, or of quick-setting type. The advantage of these glues is that they can be laid in a very fine layer (<1 μm) while preserving their covering capacity and required properties for immediate bonding by pressure. The glue thickness can be adjusted to within a few micrometers to perfect quality of application.

Advantageously, the glue is chosen from the group comprising glues of polyester, polyurethane, epoxy, phenoxy or cyanoacrylate type.

According to a particular embodiment, the method also comprises, before the bonding steps, a step in which a layer of electrically insulating material is deposited on the layer of electrically conductive material prior to applying the glue.

According to another particular embodiment, the method also comprises, after step e), a step during which an electrically insulating layer is deposited on the layer of electrically conductive material of the elementary stack.

According to another particular embodiment, a layer of electrically insulating material is deposited on the surface of the receiving substrate. This embodiment is of particular interest when the receiving substrate is a stack of layers of electrically insulating material and of layers of electrically conductive material.

According to another particular embodiment, a layer of electrically insulating material is deposited on the peel-off surface of the deposit substrate, prior to the depositing of the layer of electrically conductive material performed at step a).

The addition of one or more layers of an electrically insulating material makes it possible to perfect the uniformity of the glue layers, the electric insulation of the elements in electrically conductive material, the parallelism of the stacks or further to impart a desired internal geometry to the composite material. This electrically insulating material acts as fixed space and as insulator between the layers of electrically conductive material during the structuring of the multilayer. It preferably has sufficient covering capacity and good chemical resistance to glue solvents. Advantageously, this electrically insulating material is combined with a wetting agent to facilitate application of the glue and to avoid the onset of any defect in the glue layer during evaporation of the solvents.

Advantageously, the electrically insulating material is chosen from among an inorganic, organic or mixed varnish, a compound obtained by a sol-gel type process, and a primer reacting with the layer of electrically conductive material.

Advantageously, the thickness of the glue layer is between 0.3 and 10 μm. The thickness is adapted according to the type of glue used so as to give the best mechanical resistance to the composite multilayer.

Advantageously, the thickness of the layer of electrically insulating material is between 0.1 et 20 μm.

Advantageously, the layer of glue and/or the layer of electrically insulating material is applied, on unwinding, by smooth or patterned coating. Smooth rollers may be used for applying the glue or the electrically isolating material in a continuous thickness, and profiled or patterned rollers to deposit the glue or the electrically insulating material in discontinuous manner. The presence of patterns in the layer of glue or of electrically insulating material can allow contact between the layers of electrically conductive material.

According to a particular embodiment, hard varnishes are used, preferably inorganic. These hard varnishes may be deposited in the form of continuous thin films or in a pattern. The mechanical properties of these varnishes, through their hardness, make it possible to impose a geometry between the layers of electrically conductive materials.

According to another embodiment, flexible varnishes are used, preferably organic. With these varnishes it is possible to impose a space between the layers of electrically conductive material and to insulate them electrically while preserving the flexibility of the final composite multilayer film and its handling capacity. In this way it is possible to obtain thicker multilayer films than with a hard varnish while preserving the necessary flexibility for optional subsequent winding steps.

According to a particular embodiment, the layers of electrically insulating material are made of materials having the same chemical compositions.

According to another particular embodiment, the layers of material whether electrically insulating or not, are made of materials having different chemical compositions. For example, layers of material whether electrically insulating or not having different chemical compositions may be applied in particular patterns with multiple passes.

According to a particular embodiment, the bonding steps are conducted using a technique chosen from among calendering, plating or tensioned co-winding. Advantageously, plating is achieved by concomitant tensioned passing over return rollers.

The advantages of this method compared with prior art methods are numerous. With the method of the invention it is possible in particular to rapidly obtain a continuous, adjustable composite multilayer. Firstly, the area of the composite multilayer obtained is only limited by the size of the deposit substrates and not by the method itself. Secondly, composite multilayers can be obtained having a three-dimensional architecture by adjusting the thickness of the layers of electrically insulating material and their periodicity. In this way a composite multilayer can be obtained which remains flexible while containing a large number of layers by using a varnish of low stiffness.

Also, the method of the invention leads to achieving high metal contents while preserving the dielectric nature of the composite multilayer. For example, a large-size composite stack may be made containing successive layers of one micrometer of insulator (varnish and glue) and of metal. The ratio of active material (metal) to the total volume of the multilayer is thereby highly increased.

The layers of electrically conductive materials vacuum deposited on a flexible substrate are often stressed by this deposit substrate. The method of the invention sets out to overcome this disadvantage by distinguishing between the deposit substrate and the substrate used in the multilayer (receiving substrate), and by disclosing how to pass from one to the other. It is therefore possible to relax the stress imposed by the deposit substrate on the electrically conductive material, which has an influence on the magnetic properties of the magneto-strictive materials. Composite multilayers are therefore obtained having insulator thicknesses in the desired range and whose layers are stress-free.

The invention also concerns a radioelectric inductor characterized in that it comprises a composite multilayer fabricated using the above-described method.

Advantageously, the composite multilayer of this radioelectric inductor has layers of electrically conductive material which have a thickness of between 0.1 and 3 μm, and layers of electrically insulating material and glue whose thickness lies between 0.5 and 50 μm.

### BRIEF DESCRIPTION OF THE DRAWINGS

The invention will be more readily understood and other advantages and characteristics will become apparent on reading the following description given as a non-restrictive example accompanied by the appended drawings in which:

FIG. 1 shows the fabrication steps of a composite multilayer according to the invention,

FIG. 2 illustrates a composite multilayer of the invention,

FIG. 3 is a particular case of the invention in which the layer of electrically insulating material is applied in a pattern,

FIG. 4 shows three-dimensional composite multilayer according to the invention,

FIG. 5 illustrates a fabrication step of a cylindrical composite according to the invention.

### DETAILED DESCRIPTION OF PARTICULAR EMBODIMENTS

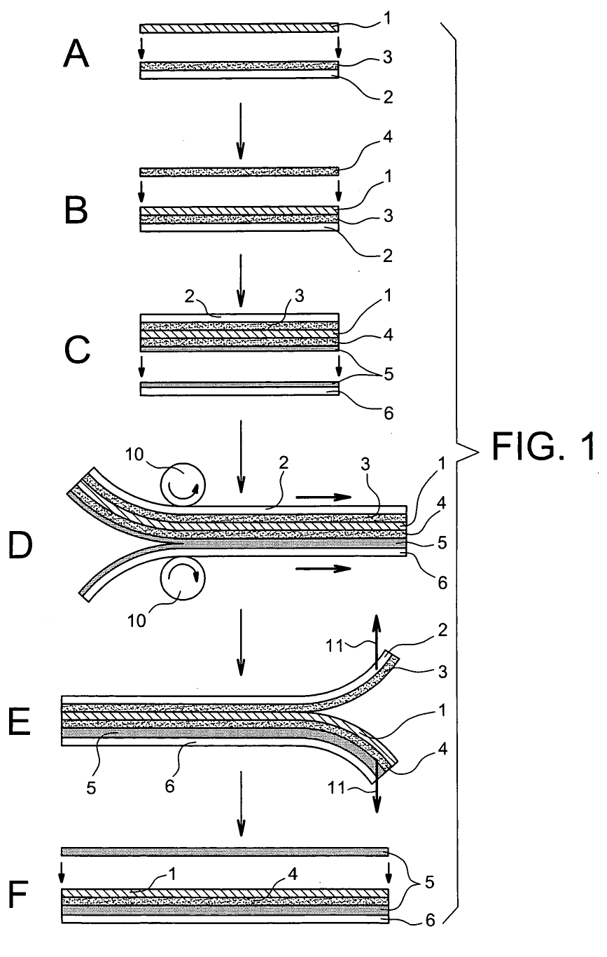

The different steps of the method for fabricating a multiplayer composite material according to the invention are described in steps A to F in FIG. 1.

During a first stage (see step A in FIG. 1), a layer of amorphous ferromagnetic material 1 is deposited on a substrate. This substrate consists of an organic polymer film 2 on which a transfer layer 3 is previously deposited. Optionally a protective layer is deposited on the transfer layer 3 to protect said layer against any possible deterioration phenomena should the deposits be vacuum deposited. This layer will therefore form part of the final stack. This protective layer may hence itself be in an electrically insulating material and form a hard insulator preventing electric contacts in the final composite. The assembly consisting of layers 2 and 3 forms a peel-off film. The depositing of the layer of amorphous ferromagnetic material 1 may be made by magnetron-assisted sputtering for example.

Thereafter, according to step B in FIG. 1, a layer of electrically insulating material 4 is deposited on the layer of amorphous ferromagnetic material 1.

According to step C in FIG. 1, a layer of glue 5 required for structuring the composite is then deposited on the layer of electrically insulating material 4 and a second layer of glue 5 is deposited on the receiving substrate 6 on which it is intended to transfer the electrically insulating deposit 4. The receiving substrate 6 may be a flexible reinforcing film with a thickness of between 1.5 and 100 μm in polyester or polyimide for example, or any other polymer or flexible material.

The glued receiving substrate 6,5 and the glued transferable film 2,3,4,1,5 are then positioned facing one another. To promote bonding between the two parts and so as not to trap any air bubbles, it is possible, as shown in step D FIG. 1, to calender the two films between two reels 10 rotating in opposite direction. In some cases, mere contacting is sufficient to conduct the assembly step of these films. The assembly must be precise especially if the periodicity of patterns is to be heeded.

A composite is then obtained comprising an additional deposit layer separated from the previous one by the layer or layers of glue. The receiving substrate may be a film or an object on which the film is plated.

A traction force 11 is then exerted on the multilayer consisting of layers 2,3,4,1,5,6 on either side of the transfer layer 3 (see step E in FIG. 1). The ferromagnetic layer 1 is separated from its deposit substrate 2,3. On one side this gives a lamellar composite 4,1,5,6 containing the ferromagnetic layer, and on the other side the deposit substrate with the transfer layer 2,3.

To obtain a composite formed of alternating ferromagnetic layers and dielectric layers, the above steps must be repeated several times: a layer of glue 5 (see step F in FIG. 1) is deposited on the multilayer 4,1,5,6 containing the first transferred ferromagnetic layer and the fabrication process is then resumed by the glue application step, substrate 5,6 then being replaced by the multilayer 4,1,5,6. It is possible to deposit this layer of glue 5 on the new film to be transferred (as is the case in step B of FIG. 1) or on both faces.

It is to be noted that the insulating layers and ferromagnetic layers are not necessarily the same: composite multilayers can be easily made using mixed compositions, both for the deposited ferromagnetic layer and for the insulator.

Once the composite with the desired number of ferromagnetic layers has been fabricated, a final glue cross-linking step must optionally be allowed if the glue used is not a contact glue.

It is to be noted that the previously described operations, i.e. the steps of depositing the ferromagnetic layer, glue application, assembling and peeling off may be made continuously. The composite multilayer may be structured by successive stacking through the counter gluing, on unwinding, of layers that are continuously glued and peeled off their deposit substrates on which they were initially deposited.

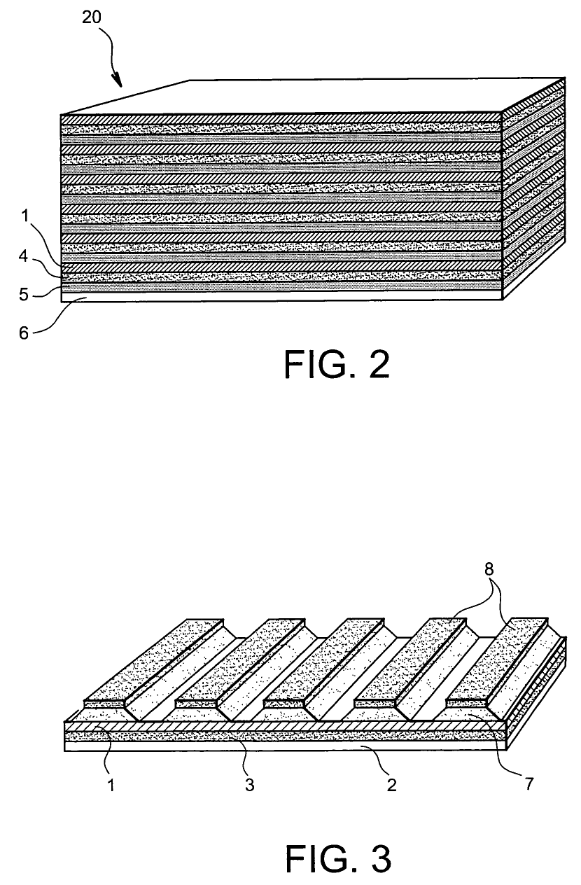

On completion, a multilayer 20 is obtained in the form of an assembly of wafers 4,1,5 on a receiving substrate 6 as shown in FIG. 2. With all the added layers, i.e. the layers of glue, ferromagnetic and insulating materials, the ferromagnetic-insulator multilayer stack has thicknesses of electrically insulating material of between 0.5 and 50 μm and thicknesses of ferromagnetic layers of between 0.1 and 3 μm. It is to be noted that the receiving substrate 6, used for the depositing phases or for fabricating the composite multilayer, may be maintained or removed at any time of the implementation process of the end product, depending on its use.

In order to impart the desired magnetic, orientation and handling properties to the multilayers, they may be cut or grooved mechanically, chemically or thermally and undergo various thermomagnetic and protective treatments. At this stage of the fabrication process, it is possible for example to conduct thermomagnetic annealing of the multilayer in order to optimise the magnetic properties of the electrically conductive material or materials. This annealing could also have been performed on the deposit substrate containing the layers of electrically conductive and insulating materials before transfer onto the receiving substrate.

It is to be noted that the end product obtained may also be in the form of a multilayer film wound around a central mandrel. In this case, the multilayer film must be tension wound as it is fabricated, the pressure exerted by the layers on each other being sufficient to ensure the cohesion of the composite multilayer.

To improve the covering properties of the glue layer, being in an electrically insulating material, and to ensure the parallelism of the superimposed layers or, on the contrary, to impart an internal geometry to the composite multilayer, it is also possible to deposit a layer of varnish on the multilayer 4,1,5,6 before the glue application step. In this case, consideration must be given to the presence of this layer to determine the thickness of the insulator between the layers of ferromagnetic materials. These varnish layers are deposited accordingly not on the multilayer but on the peel-off film of the following step or on both faces.

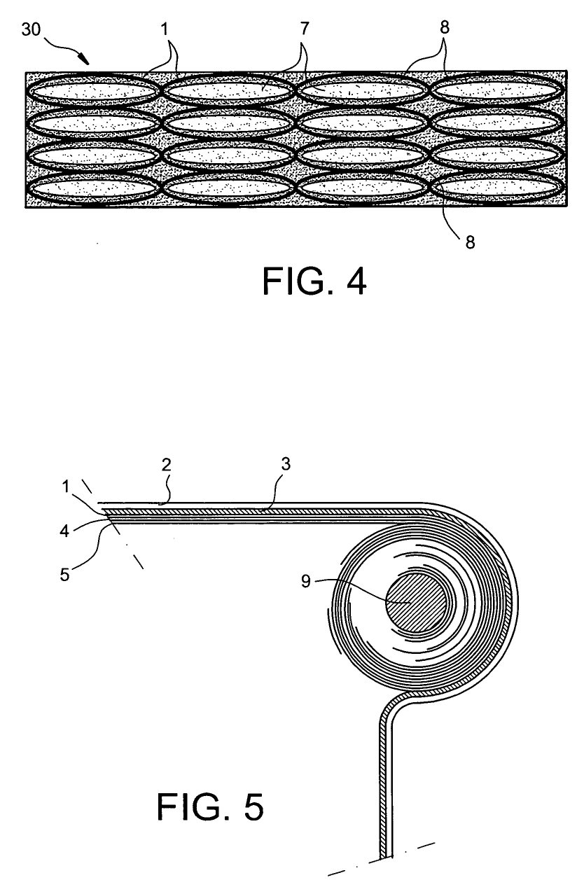

The structuring of ferromagnetic films coated with insulator in a periodic pattern makes it possible to create bi- or tri-dimensional composites with periodic, controlled contact distances between the ferromagnetic layers. In this manner a composite can be obtained having a controlled percolation rate. In FIG. 3 the deposit substrate consisting of a polymer layer 2 and a transfer layer 3 receives a layer of electrically conductive material 1. A layer of varnish 7 is then deposited thereupon according to a pre-defined pattern. Glue 8 is subsequently deposited in selective manner so that the areas not coated with varnish are not coated with glue. On assembly, care is taken to position the insulator patterns to ensure the desired periodicity of contacts. The distances between the contact points of the ferromagnetic layers may for example be fixed at a fraction of the wavelength of the incident field. FIG. 4 shows the composite 30 in three dimensions obtained after assembling stacks having varnish patterns. Pads 7 of varnish judiciously arranged on the transferable and receiving films of ferromagnetic material 1, the selective coating of glue 8 on varnished areas 7 and the adjusting of the position of the films during fabrication of the multilayer enable a percolating composite to be obtained having controlled contact periodicity between the ferromagnetic layers.

According to the invention, the stacks may be wound around a receiving substrate whether cylindrical or not, driven in rotational movement about a roll or ring for example. In this case the receiving substrate 6 for transferred films 2,3,4,1,5 may directly be a ring 9 driven in rotational movement on which the composite film is laid and freed of the deposit substrate 2,3 after partial winding as illustrated in FIG. 5. In more detail, a stack is made on a deposit substrate according to the method for fabricating a composite multilayer of the invention, then a layer of glue is deposited on the layer of electrically conductive material of stack 2,3,4,1,5. The stack obtained is then contacted with a ring which in this case acts as receiving substrate. This ring is driven in rotational movement. Finally, the deposit substrate 2,3 is separated from the remainder of the stack after the stack has been partially wound around the ring.

The uses of the composite multilayer after fabrication are multiple. It may be integrated into high frequency devices (a microstrip line for example) for electronic applications such as magnetic switches, filters. It may be integrated in inductor devices for radio applications or be applied to sensitive components to protect them against electromagnetic pulses or disturbances. A few examples of particular embodiments of composite multilayers are given below.

In a first example, the deposit substrate provided by MALAHIDE®, consists of a polyethylene-terephtalate (PET) film having a thickness of 50 μm on which are successively deposited a transfer layer, a varnish layer and a protective aluminium layer. Then, on unwinding, a thickness of 0.8 μm of CO₈₈Nb₇Zr₅ alloy (atomic percentage [at %]) is deposited by magnetron-assisted sputtering on the aluminium layer. On the ferromagnetic film, by coating on unwinding, a 0.3 μm layer of protective silica is then deposited, obtained from a colloidal silica gel LUDOX HS40®. On the layer of varnish, still by coating on unwinding, a 1 μm layer of E505 glue is deposited, available from Epotecny®.

The whole is assembled on a receiving substrate and the transfer layer is removed and the PET layer after cross-linking of the glue is completed.

These steps are repeated 25 times until a lamellar composite is obtained having a thickness of 50 μm, and a 40% content by volume of magnetic material.

The composite multilayer obtained, after being cut into the desired size, may be inserted in a microstrip line to obtain a frequency tuneable filter.

In a second example, the deposit substrate, provided by MALAHIDE®, consists of a polyethylene-terephtalate (PET) film having a thickness of 50 μm on which are successively deposited a transfer layer, a varnish layer then a protective aluminium layer. Then, on unwinding, a 2 μm thickness of CO₈₈Nb₇Zr₅ alloy (at %) is deposited on the aluminium layer by magnetron-assisted sputtering. On this, by coating on unwinding, a 1 μm layer of E505 glue is deposited provided by Epotecny®, and the stack so formed is wound around a ring by continuously detaching the deposit substrate after three quarters of a turn. The ferromagnetic volume content of this ring is 66%. In this manner a cylindrical radio-frequency inductor composite is obtained.

In the third and last example, the deposit substrate provided by MALAHIDE®, consists of a PET layer 50 μm thick, on which are successively deposited a transfer layer, a varnish layer and a protective aluminium layer. On unwinding using magnetron-assisted sputtering, a 2 μm thickness of CO₈₈Nb₇Zr₅ alloy (at %) is deposited on the aluminium layer. During the separation step of the deposit substrate from the varnish layer, a film of mylar 1.5 μm thick is inserted in the stack formed of layers of varnish, aluminium and alloy and co-wound around a ring.

### BIBLIOGRAPHY

[1] E, SALAHUN, G. TANNE, P. QUÉFFELEC, M. Le FLOCH, A. L. ADENOT, A. ACHER, Application of Ferromagnetic Composite in Different Planar Tuneable Microwave devices, Microwave and Optical Technology Letters, vol. 30, no. 4, pp 272-276, 2001.
[2] R. LEBOURGEOIS et al., Journal of Magnetism and Magnetic Materials, 254-255, 608-611, 2003.
[3] R. LEBOURGEOIS et al., IEEE Transactions on Magnetics, vol. 38, no 5, September 2002.

1. Method for fabricating a composite multilayer comprising a stack of layers of electrically conductive material alternating with layers of electrically insulating material, said method being characterized in that it comprises the following steps:
a) depositing an electrically conductive material, in layer form, on a peel-off surface of a deposit substrate,
b) bonding, by application of the glue in electrically insulating material, a layer of said electrically conductive material deposited on a peel-off surface of a deposit substrate, onto a receiving substrate,
c) separating, by peeling off, the deposit substrate from the layer of electrically conductive material adhering to the receiving substrate, this separation providing an elementary stack comprising a layer of glue and a layer of electrically conductive material,
d) bonding, by applying of the glue in electrically insulating material, another layer of said electrically conductive material deposited on a peel-off surface of a deposit substrate, onto the previously obtained elementary stack,
e) separating, by peeling off, the deposit substrate from the layer of electrically conductive material adhering to the elementary stack previously obtained, this separation providing a subsequent elementary stack comprising a layer of glue and a layer of electrically conductive material,
the method comprising the repetition of steps d) and e) as many times as necessary to obtain a stack having the desired number of elementary stacks.

2. Fabrication method according to claim 1, wherein the deposit substrate consists of a polymer film and of one or more transfer layers.

3. Fabrication method as in claim 1, wherein the receiving substrate is driven in rotational movement.

4. Fabrication method as in claim 3, wherein the separation steps are conducted after partial winding of the elementary stack around the substrate.

5. Fabrication method as in claim 1, wherein the steps of depositing, bonding and separation are continuously-conducted.

6. Fabrication method as in claim 1, wherein the depositing of the electrically conductive material is conducted by magnetron-assisted sputtering.

7. Fabrication method as in claim 1, wherein the electrically conductive material is a ferromagnetic material.

8. Fabrication method according to claim 7, wherein the electrically conductive material is chosen from among a cobalt, iron or nickel-based amorphous ferromagnetic alloy.

9. Fabrication method as in claim 1, wherein the layers of electrically conductive material consist of materials having the same chemical compositions and/or the same electromagnetic properties.

10. Fabrication method as in claim 1, wherein the layers of electrically conductive material consist of materials having different chemical compositions and/or electromagnetic properties.

11. Fabrication method as in claim 1, wherein the thickness of the layer of electrically conductive material lies between 0.1 and 10 times the skin depth of the material.

12. Fabrication method as in claim 1, wherein the layer of glue is deposited on the peel-off surface of a deposit substrate, on the receiving substrate or on both.

13. Fabrication method as in claim 1, wherein the glue can be activated by pressure or temperature.

14. Fabrication method as in claim 1, wherein the glue is chosen from among the group comprising glues of polyester, polyurethane, epoxy, phenoxy or cyanoacrylate type.

15. Fabrication method as in claim 1, further comprising, before the bonding steps, a depositing step to deposit a layer of electrically insulating material on the layer of electrically conductive material, prior to applying the glue.

16. Fabrication method as in claim 1, further comprising, after step e), a depositing step to deposit a layer of electrically insulating material on the layers of electrically conductive material of the elementary stack.

17. Fabrication method as in claim 1, wherein a layer of electrically insulating material is deposited on the surface of the receiving substrate.

18. Fabrication method as in claim 1, wherein a layer of electrically insulating material is deposited on the peel-off surface of the deposit substrate, prior to the depositing of the layer of electrically conductive material conducted at step a).

19. Fabrication method as in claim 15, wherein the electrically insulating material is chosen from among an inorganic, organic or mixed varnish, a compound obtained with a sol-gel type process, and a primer reacting with the layer of electrically conductive material.

20. Fabrication method as in claim 1, wherein the thickness of the glue layer lies between 0.3 and 10 μm.

21. Fabrication method as in claim 15, wherein the thickness of the layer of electrically insulating material lies between 0.1 and 20 μm.

22. Fabrication method as in claim 1, wherein the glue layer and/or the layer of electrically insulating material is applied on unwinding by smooth coating or coating in a pattern.

23. Fabrication method as in claim 1, wherein the layers of electrically insulating material consist of materials having the same chemical compositions.

24. Fabrication method as in claim 1, wherein the layers of material whether electrically insulating or not consist of materials having different chemical compositions.

25. Fabrication method as in claim 1, wherein the bonding steps are made using a technique chosen from among calendering, plating or tensioned co-winding.

26. Radioelectric inductor characterized in that it comprises a composite multilayer fabricated according to claim 1.

27. Radioelectric inductor according to claim 26, wherein the composite multilayer has layers of electrically conductive material whose thickness lies between 0.1 and 3 μm and layers of electrically insulating material and of glue whose thickness lies between 0.5 and 50 μm.
